(19) United States
(12) Patent Application Publication
(10) Pub. No.: US 2011/0263079 A1
(43) Pub. Date: Oct. 27, 2011

(54) INTERFACE PROTECTION LAYAER USED IN A THIN FILM TRANSISTOR STRUCTURE

(75) Inventor: Shi-Qing Wang, San Jose, CA (US)

(73) Assignee: APPLIES MATERIALS, INC., Santa Clara, CA (US)

(21) Appl. No.: 13/088,162

(22) Filed: Apr. 15, 2011

Related U.S. Application Data
(60) Provisional application No. 61/327,415, filed on Apr. 23, 2010.

(51) Int. Cl. H01L 21/302

(52) U.S. Cl. 438/149; 257/E21.214

(57) ABSTRACT

Embodiments of the disclosure generally provide methods of using an interface protection layer disposed between an active layer and a source-drain metal electrode layer. In one embodiment, a method for forming an interface protection layer in a thin film transistor includes providing a substrate having an active layer formed thereon, wherein the active layer is a metal oxide layer, forming an interface protection layer on a portion of the active layer, and forming a source-drain electrode layer on the interface protection layer.

### CROSS-REFERENCE TO RELATED APPLICATIONS

This application claims benefit of U.S. Provisional Application Ser. No. 61/327,415 filed Apr. 23, 2010 (Attorney Docket No. APPM/14581L), which is incorporated by reference in its entirety.

### BACKGROUND OF THE INVENTION

1. Field of the Invention

Embodiments of the present invention generally relate to methods for forming an interface protection layer that may protect layers in an etching process. More particularly, this invention relates to methods for forming an interface protection layer that may protect layers in an etching process in thin film transistors devices.

2. Description of the Related Art

Plasma display panels and liquid crystal displays are frequently used for flat panel displays. Liquid crystal displays (LCD) generally contain two transparent substrates joined together with a layer of a liquid crystal material sandwiched therebetween. The transparent substrate may be a semiconductor substrate, glass, quartz, sapphire, flexible or a clear plastic film. The LCD may also contain light emitting diodes for back lighting.

As the resolution requirements for liquid crystal displays increase, it has become desirable to control a large number of separate areas of the liquid crystal cell, called pixels. In a modern display panel, more than 1,000,000 pixels may be present. At least the same number of transistors is formed on the glass substrate so that each pixel can be switched between an energized and de-energized state relative to the other pixels disposed on the substrate.

FIG. 1 depicts a conventional thin film transistor device 150 disposed on a substrate 100. A gate electrode 102 is formed and patterned on the substrate 100 followed by a gate insulator layer 104. An active layer 106 is formed on the gate insulator layer 104. The active layer 106 is often selected from a transparent metallic oxide material that has high electron mobility as well as low temperature manufacture process requirement so that allows flexible substrate materials, such as plastic materials may be processed at low temperatures without substrate damage. After formation of the active layer 106, a source-drain metal electrode layer 108 is then disposed thereon to form the thin film transistor device 150. Subsequently, a back-channel-etching (BCE) process is performed to form a channel 110 in the thin film transistor device 150. During back-channel-etching (BCE) process, the aggressive etchants used during the etching process may adversely over etch and attack the underlying active layer 106 formed in the device 150, thereby deteriorating film quality and electric performance of the thin film transistor device 150.

Therefore, there is a need for a method for manufacturing the thin film transistor devices having improved electrical performance and stability.

### SUMMARY OF THE INVENTION

Embodiments of the disclosure generally provide methods of using a interface protection layer disposed between an active layer and a source-drain metal electrode layer. In one embodiment, a method for forming an interface protection layer in a thin film transistor includes providing a substrate having an active layer formed thereon, wherein the active layer is a metal oxide layer, forming an interface protection layer on a portion of the active layer, and forming a source-drain electrode layer on the interface protection layer.

In another embodiment, a method for forming an interface protection layer in a thin film transistor includes forming an interface protection layer on a portion of a metal oxide layer disposed on a substrate, forming a source-drain electrode layer on the interface protection layer, etching the source-drain electrode layer to form a channel in the source-drain electrode layer that exposes a portion of the interface protection layer, and selectively oxidizing or nitridizing the portion of the interface protection layer exposed through the source-drain electrode layer in the presence of a plasma formed in an oxygen containing environment or an nitrogen containing environment.

In yet another embodiment, a method for forming an interface protection layer in a thin film transistor includes forming an interface protection layer having a thickness less than 500 Å on a portion of an active layer, wherein the interface protection layer is a Ti layer or a Ta layer and the active layer is a metal oxide layer, forming a source-drain electrode layer on the interface protection layer, etching the source-drain electrode layer to form a channel in the source-drain electrode layer that exposes a portion of the interface protection layer, exposing the portion of the interface protection layer exposed through the source-drain electrode layer to an oxygen containing plasma environment or a nitrogen containing plasma environment, and selectively oxidizing or nitridizing an entire thickness of the exposed portion of the interface protection layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a sectional view of a conventional thin film transistor device structure;

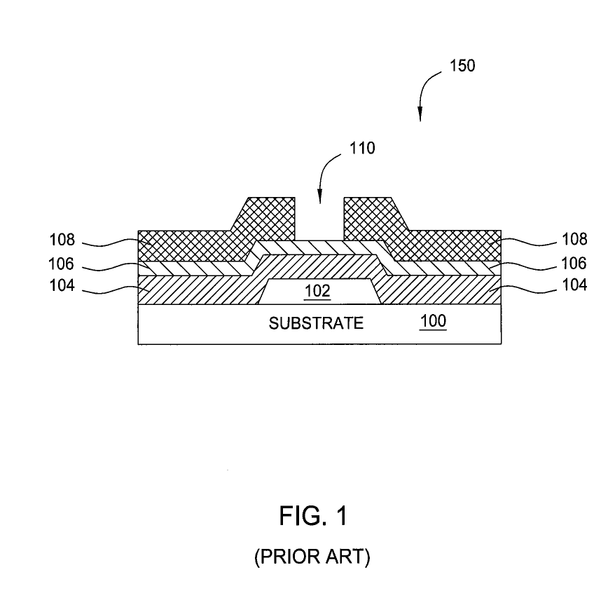

FIG. 2 depicts a sectional view of the processing chamber that may be used to deposit a microcrystalline silicon layer in accordance with one embodiment of the present invention;

FIG. 3 depicts a process flow diagram of one embodiment of a method of forming an interface protection layer in a device structure in accordance with an embodiment of the present invention; and

FIG. 4A-E depicts a sequence of fabrication stages of a device structure having a microcrystalline silicon layer formed in accordance with an embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the disclosure generally provide methods of using an interface protection layer disposed between an active layer and a source-drain metal electrode layer. In one embodiment, the interface protection layer may be used in a TFT device, photodiodes, semiconductor diode, light-emitting diode (LED), or organic light-emitting diode (OLED), or other suitable applications. The interface protection layer advantageously provides a protective interface that prevents the underlying device structure from being damage by reactive etchants generated during a back-channel-etching (BCE) process. The interface protection layer is selected from a material that can maintain efficient electrical performance of transistor and diode devices, while protecting the device structure from damage.

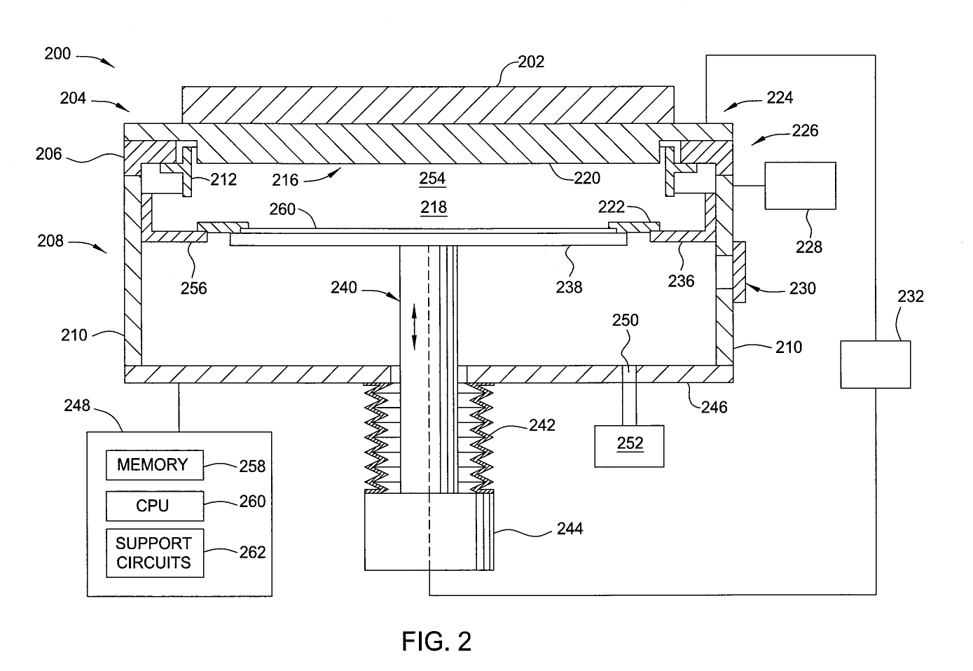

FIG. 2 illustrates an exemplary reactive sputter process chamber 200 suitable for forming an interface protection layer according to one embodiment of the invention. The process chamber 200 may be part of a vacuum processing system having multiple processing chambers 200. One example of the process chamber that may be adapted to benefit from the invention is a physical vapor deposition (PVD) process chamber, available from Applied Materials, Inc., located in Santa Clara, Calif. It is contemplated that other sputter process chambers, including those from other manufactures, may be adapted to practice the present invention.

The process chamber 200 includes a chamber body 208 having a processing volume 218 defined therein and enclosed by a lid assembly 204. The chamber body 208 has sidewalls 210 and a bottom 246. The dimensions of the chamber body 208 and related components of the process chamber 200 are not limited and generally are proportionally larger than the size of a substrate 270 to be processed therein. As such, any suitable substrate size may be processed in a suitable sized process chamber. Examples of suitable substrate sizes include substrates having a plan surface area of about 2000 or more square centimeters.

The chamber body 208 may be fabricated from aluminum or other suitable material. A substrate access port 230 is formed through the sidewall 210 of the chamber body 208, facilitating the transfer of the substrate 270 (i.e., a solar panel or a flat panel display substrate, a plastic or flexible substrate, a semiconductor wafer, or other workpiece) into and out of the process chamber 200. The access port 230 may be coupled to a transfer chamber and/or other chambers of a substrate processing system.

A gas source 228 is coupled to the chamber body 208 to supply process gases into the processing volume 218. Examples of process gases that may be provided by the gas source 228 include inert gases, non-reactive gases, and reactive gases. In one embodiment, process gases provided by the gas source 228 may include, but not limited to, argon gas (Ar), helium (He), nitrogen gas (N₂), oxygen gas (O₂), and H₂O, among others.

A pumping port 250 is formed through the bottom 246 of the chamber body 208. A pumping device 252 is coupled to the process volume 218 to evacuate and control the pressure therein. In one embodiment, the pressure level of the process chamber 200 may be maintained at about 1 Torr or less.

The lid assembly 204 generally includes a target 220 and a ground shield assembly 226 coupled or positioned proximate thereto. The target 220 provides a material source that can be sputtered and deposited onto the surface of the substrate 270 during a PVD process. The target 220 or target plate may be fabricated from a material utilized as a deposition specie. A high voltage power supply, such as a power source 232, is connected to the target 220 to facilitate sputtering materials from the target 220. In one embodiment, the target 220 may be fabricated from a material containing titanium (Ti), tantalum (Ta) metal or other suitable materials. In another embodiment, the target 320 may be fabricated by materials including titanium (Ti) alloy or tantalum (Ta) alloy and the like.

The target 220 generally includes a peripheral portion 224 and a central portion 216. The peripheral portion 224 is disposed over the sidewalls 210 of the chamber 200. The central portion 216 of the target 220 may have a curvature surface slightly extending towards the surface of the substrate 270 disposed on a substrate support 238. The spacing between the target 220 and the substrate support 238 is maintained between about 50 mm and about 150 mm. It is noted that the dimension, shape, materials, configuration and diameter of the target 220 may be varied for specific process or substrate requirements. In one embodiment, the target 220 may further include a backing plate having a central portion bonded and/or fabricated from a material desired to be sputtered onto the substrate surface. The target 220 may also include a plurality of tiles or segment materials that together form the target.

The lid assembly 204 may further comprise a magnetron assembly 202 mounted above the target 220 which enhances efficient sputtering of material from the target 220 during processing. Examples of the magnetron assembly include a linear magnetron, a serpentine magnetron, a spiral magnetron, a double-digitated magnetron, a rectangularized spiral magnetron, among others.

The ground shield assembly 226 of the lid assembly 204 includes a ground frame 206 and a ground shield 212. The ground shield assembly 226 may also include other chamber shield members, target shield member, dark space shield, and dark space shield frame. The ground shield 212 is coupled to the peripheral portion 224 by the ground frame 206 defining an upper processing region 254 below the central portion 216 of the target 220 in the process volume 218. The ground frame 206 electrically insulates the ground shield 212 from the target 220 while providing a ground path to the chamber body 208 of the process chamber 200 through the sidewalls 210. The ground shield 212 constrains plasma generated during processing within the upper processing region 254 so that dislodged target source material from the central portion 216 of the target 220 is mainly deposited on the substrate surface rather than chamber sidewalls 210. In one embodiment, the ground shield 212 may be formed by one or more components.

A shaft 240 that extends through the bottom 246 of the chamber body 208 couples the substrate support 238 to a lift mechanism 244. The lift mechanism 244 is configured to move the substrate support 238 between a lower transfer position and an upper processing position. A bellows 242 circumscribes the shaft 240 and is coupled to the substrate support 238 to provide a flexible seal therebetween, thereby maintaining vacuum integrity of the chamber processing volume 218.

A shadow frame 222 is disposed on the periphery region of the substrate support 238 and is configured to confine deposition of source material sputtered from the target 220 to a desired portion of the substrate surface. When the substrate support 238 is in a lowered position, the shadow frame 222 is suspended above the substrate support 238 from a lip 256 of a chamber shield 236 that extends from the sidewall 210 of the chamber body 208. As the substrate support 238 is raised to the upper position for processing, an outer edge of the substrate 270 disposed on the substrate support 238 contacts the shadow frame 222, causing the shadow frame 222 to be lifted and spaced away from the chamber shield 236. In or while moving into the lowered position, lift pins (not shown) are selectively moved through the substrate support 238 to lift the substrate 270 above the substrate support 238 to facilitate access to the substrate 270 by a transfer robot or other suitable transfer mechanism.

A controller 248 is coupled to the process chamber 200. The controller 248 includes a central processing unit (CPU) 260, a memory 258, and support circuits 262. The controller 248 is utilized to control the process sequence, regulating the gas flows from the gas source 228 into the chamber 200 and controlling ion bombardment of the target 220. The CPU 260 may be of any form of a general purpose computer processor that can be used in an industrial setting. The software routines can be stored in the memory 258, such as random access memory, read only memory, floppy or hard disk drive, or other form of digital storage. The support circuits 262 are conventionally coupled to the CPU 260 and may comprise cache, clock circuits, input/output subsystems, power supplies, and the like. The software routines, when executed by the CPU 260, transform the CPU into a specific purpose computer (controller) 248 that controls the process chamber 200 such that the processes are performed in accordance with the present invention. The software routines may also be stored and/or executed by a second controller (not shown) that is located remotely from the chamber 200.

During processing, the target 220 and the substrate support 238 are biased relative to each other by the power source 232 to maintain a plasma formed from the process gases supplied by the gas source 228. The ions from the plasma are accelerated toward and strike the target 220, causing target material to be dislodged from the target 220. The dislodged target material forms a layer on the substrate 270. In embodiments where certain process gases are supplied into the chamber 200, the dislodged target material and the process gases present in the chamber 200 react to forms a composite film on the substrate 270.

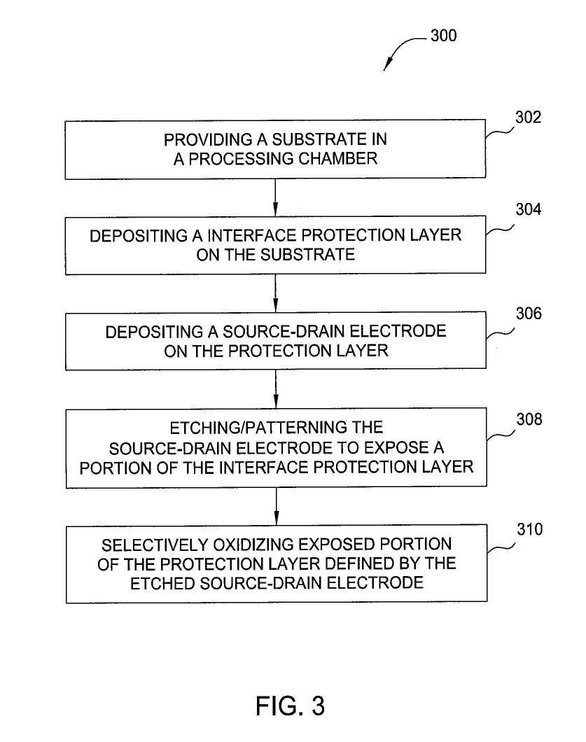

FIG. 3 depicts a flow diagram of one embodiment of a method 300 for forming an interface protection layer in a thin-film transistor device that may be practiced in the chamber 200, as described in FIG. 2, or other suitable process chamber. The method 300 illustrates a method of fabricating an interface protection layer and a device structure that may be suitable for using in TFT devices, diode devices, or among others.

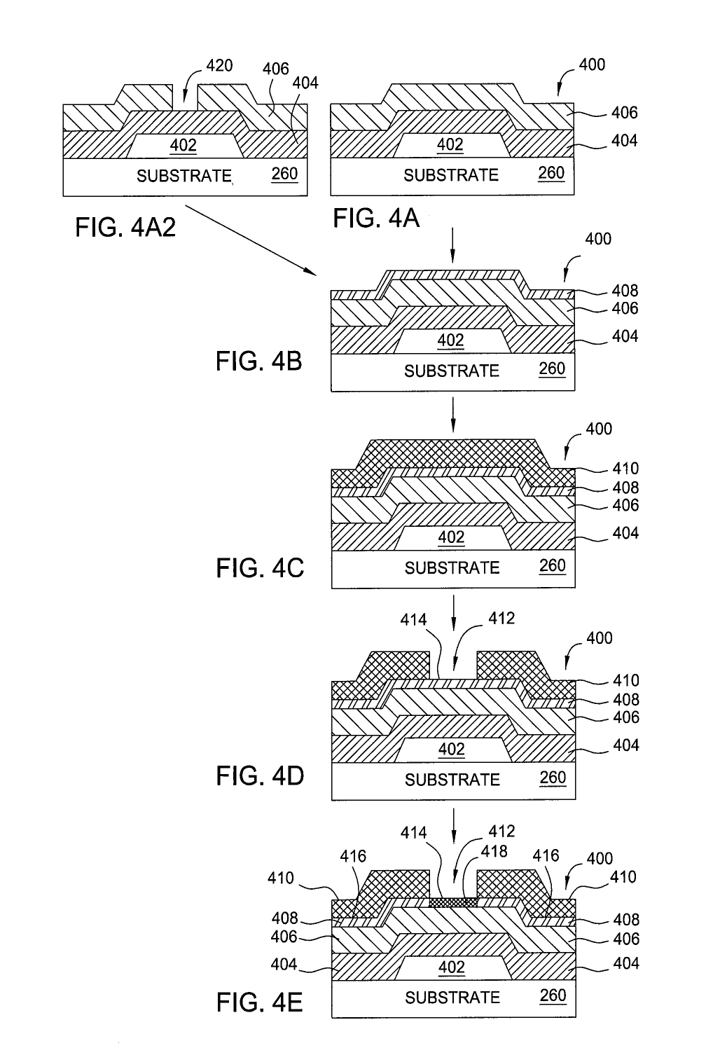

The method 300 begins at step 302 by providing the substrate 270, as shown in FIG. 4A, in a process chamber, such as the process chamber 200 depicted in FIG. 2, utilized to form a thin-film transistor device 400 thereon. The substrate 270 may have a gate electrode layer 402, a gate insulator layer 404 and an active layer 406 previously formed thereon. It is noted that the substrate 270 may have different combination of films, structures or layers previously formed thereon to facilitate forming different device structures on the substrate 270. In one embodiment, the substrate 270 may be any one of glass substrate, plastic substrate, polymer substrate, metal substrate, singled substrate, roll-to-roll substrate, or other suitable transparent substrate suitable for forming a thin film transistor thereon. In one embodiment, the gate electrode layer 402 may be fabricated from any suitable metallic materials, such as indium tin oxide (ITO), indium zinc oxide (IZO), indium tin zinc oxide (ITZO), aluminum (Al), tungsten (W), chromium (Cr), tantalum (Ta), molybdenum (Mo), or combination thereof. Suitable materials for the gate insulating layer 404 may be silicon oxide (SiO₂), silicon oxynitride (SiON), or silicon nitride (SiN), or the like. Furthermore, suitable for the active layer 406 includes InGaZnO, InGaZnON, ZnO, ZnON, ZnSnO, CdSnO, GaSnO, TiSnO, CuAlO, SrCuO, LaCuOS, GaN, InGaN, AlGaN or InGaAlN, among others.

Alternatively, the substrate 270 as provided in the process chamber for processing may have the active layer 406 patterned or etched, forming a trench 420 in the active layer 406, as shown in FIG. 4A2. In this particular embodiment, the subsequent steps described in method 300 may be performed on the substrate following the topography of the patterned active layer 406 of FIG. 4A2 as described. As the description here uses the structure of FIG. 4A as the representative embodiment, the description of this embodiment of FIG. 4A2 is hereby omitted for sake of brevity. It is noted that any different structures or layers of active layers, gate electrode layers and gate insulating layers may be utilized to perform the present invention.

At step 304, an interface protection layer 408 is deposited on the active layer 406, as depicted in FIG. 4B. The interface protection layer 408 may be fabricated from a conductive material that can maintain desired electrical properties and performances required by the devices while serving as a good protection layer by protecting the underlying structures from damage in the subsequent processes. In one embodiment, the interface protection layer 408 may be fabricated from a metallic material, such as a titanium (Ti) containing material or tantalum (Ta) containing material, a conducting material, such as metal containing material including metal oxide layers or metal nitride layers. In yet another embodiment, the interface protection layer 408 may be a dielectric layer as needed. Examples of the target materials, as depicted in FIG. 2, that may be used for forming the interface protection layer 408 include titanium (Ti) containing material or tantalum (Ta) containing material. During sputtering, a RF bias power is applied between the target and the substrate support maintains a plasma formed from a gas mixture supplied in the process chamber 200. The ions from the gas mixture in the plasma bombard and sputter off material from the target. The sputtered material from the target deposit on the surface of the active layer 406 to form the interface protection layer 408.

In embodiments wherein a titanium (Ti) containing material is utilized the gases supplied in the gas mixture bombard the material to dislodge the material from the target, forming a titanium (Ti) layer as the interface protection layer 408 on the substrate 270. As the interface protection layer 408 is utilized to serve as an interface layer, the thickness of the interface protection layer 408 is thin, for example, thick enough to protect the underlying device structure from damage without adversely affecting the overall electrical performance of the device 400. In one embodiment, the thickness of the interface protection layer 408 is less than about 500 Å, such as less than about 100 Å.

In one embodiment, the gas mixture includes Ar gas and the Ar gas may be supplied at a flow rate between about 50 sccm and about 300 sccm, such as between about 75 sccm and about 200 sccm, for example between about 100 sccm and about 150 sccm. Alternatively, Ar gas may be provided at a flow rate per chamber volume of between about 1 sccm per chamber volume (sccm/Liter) and about 6 sccm per chamber volume (sccm/Liter), such as between about 1.6 sccm per chamber volume (sccm/Liter) and about 4 sccm per chamber volume (sccm/Liter), for example between about 2 sccm per chamber volume (sccm/Liter) and about 3 sccm per chamber volume (sccm/Liter).

Several process parameters may be regulated at step 304 while forming the interface protection layer 408. In one embodiment, a pressure of the gas mixture in the process chamber 200 is regulated between about 0 mTorr and about 100 mTorr, such as between about 1 mTorr and about 10 mTorr. The substrate temperature may be maintained between about 100 degrees Celsius and about 400 degrees Celsius, such as between about 150 degrees Celsius and about 300 degrees Celsius. The DC power may be supplied between about 0 milliWatts per centimeter square and about 100 milliWatts per centimeter square, such as between about 3 milliWatts per centimeter square and about 20 milliWatts per centimeter square, for example, about 5 milliWatts per centimeter square and about 15 milliWatts per centimeter square.

At step 306, a source-drain metal electrode layer 410 may be deposited on the interface protection layer 408, as depicted in FIG. 4C. The source-drain metal electrode layer 410 may be fabricated from a conductive material that may be patterned to define source and drain contacts of the transistor device 400. In one embodiment, the source-drain metal electrode layer 410 may be fabricated by a metallic material selected from a group consisting of copper (Cu), gold, silver (Ag), aluminum (Al), tungsten (W), molybdenum (Mo), chromium (Cr), tantalum (Ta), alloys thereof and combination thereof. In an exemplary embodiment, the source-drain metal electrode layer 410 is a copper layer.

In one embodiment, as the interface protection layer 408 and the source-drain metal electrode layer 410 are both fabricated from a conductive material, they can be both sputtered deposited in a single process chamber with multiple targets present therein. Alternatively, the interface protection layer 408 and the source-drain metal electrode layer 410 may be separately and sequentially deposited in different deposition chambers incorporated in a processing system without breaking vacuum, or it can be arranged in any suitable manner as needed. In one particular embodiment, the source-drain metal electrode layer 410 is fabricated by a copper containing material by utilizing a copper target disposed in a PVD chamber, such as the chamber depicted in FIG. 2, to sputter deposit the source-drain metal electrode layer 410 on the interface protection layer 408.

During sputtering, Ar gas may be supplied at a flow rate between about 50 sccm and about 300 sccm, such as between about 75 sccm and about 200 sccm, for example between about 100 sccm and about 150 sccm. Alternatively, Ar gas may be provided at a flow rate per chamber volume between about 1 sccm per chamber volume (sccm/Liter) and about 6 sccm per chamber volume (sccm/Liter), such as between about 1.6 sccm per chamber volume (sccm/Liter) and about 4 sccm per chamber volume (sccm/Liter), for example between about 2 sccm per chamber volume (sccm/Liter) and about 3 sccm per chamber volume (sccm/Liter).

Several process parameters may be regulated at step 306 while forming the source-drain metal electrode layer 410. In one embodiment, a pressure of the gas mixture in the process chamber 200 is regulated between about 0 mTorr and about 100 mTorr, such as between about 1 mTorr and about 10 mTorr. The substrate temperature may be maintained between about 100 degrees Celsius and about 400 degrees Celsius, such as between about 150 degrees Celsius and about 300 degrees Celsius. The DC power may be supplied between about 0 milliWatts per centimeter square and about 100 milliWatts per centimeter square, such as between about 3 milliWatts per centimeter square and about 20 milliWatts per centimeter square, for example, about 5 milliWatts per centimeter square and about 15 milliWatts per centimeter square.

At step 308, a back-channel-etching (BCE) process is performed to etch or pattern the source-drain metal electrode layer 410 so as to form a channel 412 in the source-drain metal electrode layer 410, as shown in FIG. 4D. It is noted that suitable masks, such as a photoresist layer or hardmask layer, may be utilized so as to transfer desired features, trenches, or channels into the source-drain metal electrode layer 410 as needed. The back-channel-etching (BCE) process may be any suitable etching processes, including dry etching, wet etching, ion plasma etching, or the like, which can form the channel 412 in the source-drain metal electrode layer 410. The back-channel-etching (BCE) process is performed to etch the source-drain metal electrode layer 410 until a portion 414 of the underlying interface protection layer 408 is exposed through the channel 412 to complete the back-channel-etching (BCE) process.

The underlying structures, such as the active layer 406 or other underlying layers, may be damaged in conventional device structure as they may be over etched during the back-channel-etching (BCE) process. Accordingly, the interface protection layer 408 as formed between the active layer 406 and the source-drain metal electrode layer 410 may serve as a good etch stop layer to protect the underlying structure from damage during etching. Furthermore, by good selection of the material of the interface protection layer 408, the electrical performance of the overall device 400 will not be affected.

At step 310, after the channel 412 is formed in the source-drain metal electrode layer 410 by exposing the portion 414 of the interface protection layer 408, a selective oxidation/nitridation process may be performed. The exposed portion 414 of the interface protection layer 408 is oxidized/nitridized during the selective oxidation/nitridation process, thereby forming an oxidized/nitridized exposed portion 418 in the interface protection layer 408. Oxidizing/nitridizing the exposed portion 414 of the interface protection layer 408 transforms the conductive material of the interface protection layer 408 into a conductive oxide material (or an insulating layer, depending on the starting material of the interface protection layer) that defines the oxidized/nitridized exposed portion 418 so as to prevent the underlying active layer 406 from being damaged or contaminated, thereby adversely deteriorating the electrical performance of the device 400. For example, if the interface protection layer 408 is selected as a conductive layer, after the oxidation/nitridation process, the interface protection layer 408 may be converted into a conductive oxide or conductive nitride layer. In contrast, if the interface protection layer 408 is selected as a conductive oxide or a dielectric layer, after the oxidation/nitridation process, the interface protection layer 408 may be converted into an insulating layer. Accordingly, a selective oxidation/nitridation process may be performed to selectively oxidize/nitridize only the exposed portion 414 of the interface protection layer 408 into the conductive oxide or the insulating material (e.g., a dielectric material) defining the oxidized/nitridized exposed portion 418 as depicted in FIG. 4E. Other portions 416 covered by the source-drain metal electrode layer 410 may not be substantially oxidized/nitridized as they are not exposed to be oxidized/nitridized. After the selective oxidation/nitridation process, the exposed portion 414 of the interface protection layer 408 is oxidized/nitridized into a conductive oxide material or insulating material, while unexposed portions 416 covered by the source-drain metal electrode layer 410 remained as a metallic material (e.g., conductive material or conductive oxide material) so that electrical performance of the device 400 is not affected. In one particular example wherein the interface protection layer 408 is fabricated by conductive material, such as a Ti material, after selective oxidation/nitridation, the exposed portion 414 of the interface protection layer 408 is converted into conductive oxide layer, such as a TiO₂ layer to protect the channel 412 in the device 400 while the unexposed portion 416 of the interface protection layer 408 remains as the conductive material, such as the Ti material. In one embodiment, the selective oxidation/nitridation process may be performed between about 10 seconds to about 1800 seconds.

As discussed above, as the thickness of the interface protection layer 408 is thin, such as less than about 500 Å, the oxidation/nitridation process as performed at step 310 can easily oxidize/nitridize the entire thickness of the exposed portion 414 of the interface protection layer 408 without becoming self-limiting. In one embodiment, the selective oxidation/nitridation process may be performed by a thermal oxidation/nitridation process, plasma oxidation/nitridation process, rapid thermal process (RTP), air blow process, or oxygen ambient exposure process, or any other suitable processes as needed. In one embodiment, the selective oxidation/nitridation process is performed in a CVD chamber using plasma formed from a gas mixture having at least an oxygen containing or a nitrogen containing gas. Suitable examples of the oxygen containing gas include O₂, O₃, N₂O, NO₂, CO₂, CO and the like. Suitable examples of the nitrogen containing gas include N₂O, NH₃, NO₂ and N₂. After the oxidation/nitridation process, the thickness of the interface protection layer 408 being oxidized/nitridized may become slightly thicker than the thickness of the interface protection layer 408 before the oxidation/nitridation process.

By forming the interface protection layer 408 between the active layer 406 and the source-drain electrode layer 410, the underlying active layer 406 may be protected from damage during the subsequent etching or other manufacturing process. Additionally, as the interface protection layer 408 is selected to be fabricated from a conductive material and the thickness of the interface protection layer 408 is controlled as thin as less than about 500 Å, addition of the interface protection layer 408 in the structure of the device 400 does not adversely result in an undesirable electrical performance change. Furthermore, by performing a selective oxidation/nitridation process to the exposed portion of the interface protection layer 408 uncovered by the source-drain electrode layer 410, the conductive material of the interface protection layer 408 may be converted into a conductive oxide/nitride or an insulating material so as to protect the underlying active layer 406 and also provide a sealing surface at the bottom of the channel 412.

It is noted that additional process steps may be performed in any of the step, such as from step 302 to step 310, as desired, to facilitate forming the device structure on the substrate. For example, additional process steps, such as a photoresist coating or strip process, may be performed as needed to assist transferring features to the device between the step 302 and 308. In another example, additional annealing, etching, depositing, and cleaning may also be performed between any of the steps described in method 300 as needed.

Thus, the methods described herein advantageously improve the electron performance and stability electric devices by forming an interface protection layer between an active layer and a source-drain electrode layer in a thin-film transistor device.

While the foregoing is directed to embodiments of the present invention, other and further embodiments of the invention may be devised without departing from the basic scope thereof, and the scope thereof is determined by the claims that follow.

1. A method for forming an interface protection layer in a thin film transistor comprising:
providing a substrate having an active layer formed thereon, wherein the active layer is a metal oxide layer;
forming an interface protection layer on a portion of the active layer; and
forming a source-drain electrode layer on the interface protection layer.

2. The method of claim 1, further comprising:
etching the source-drain electrode layer to form a channel in the source-drain electrode layer that exposes a portion of the interface protection layer.

3. The method of claim 2, further comprising:
selectively oxidizing or nitridizing the portion of the interface protection layer exposed through by the source-drain electrode layer.

4. The method of claim 1, wherein the interface protection layer is a Ti layer.

5. The method of claim 1, wherein the source-drain electrode layer is a copper layer.

6. The method of claim 1, wherein the active layer is fabricated from a material selected from a group consisting of InGaZnO, InGaZnON, ZnO, ZnON, ZnSnO, CdSnO, GaSnO, TiSnO, CuAlO, SrCuO, LaCuOS, GaN, InGaN, AlGaN and InGaAlN.

7. The method of claim 3, wherein the selectively oxidizing or nitridizing the portion of the interface protection layer exposed through the source-drain electrode layer comprises:
exposing the substrate to a plasma formed from a oxygen containing gas or a nitrogen containing gas.

8. The method of claim 7, wherein the oxygen containing gas includes O₂, O₃, N₂O, NO₂, CO₂ and CO and the nitrogen containing gas includes N₂O, NH₃, NO₂ and N₂.

9. The method of claim 1, wherein the interface protection layer is a conductive material.

10. The method of claim 1, wherein the interface protection layer has a thickness of less than about 500 Å.

11. The method of claim 3, wherein selectively oxidizing or nitridizing the portion of the interface protection layer exposed through the source-drain electrode layer further comprises:
converting the portion of the interface protection layer into a conductive oxide or conductive nitride layer.

12. A method for forming an interface protection layer in a thin film transistor comprising:
forming an interface protection layer on a portion of a metal oxide layer disposed on a substrate;
forming a source-drain electrode layer on the interface protection layer;
etching the source-drain electrode layer to form a channel in the source-drain electrode layer that exposes a portion of the interface protection layer; and
selectively oxidizing or nitridizing the portion of the interface protection layer exposed through the source-drain electrode layer in the presence of a plasma formed in an oxygen containing environment or an nitrogen containing environment.

13. The method of claim 12, wherein exposing the interface protection layer further comprises:
oxidizing or nitridizing an entire thickness of the exposed portion of the interface protection layer.

14. The method of claim 13, wherein oxidizing or nitridizing the exposed interface protection layer further comprises:
oxidizing or nitridizing the exposed interface protection layer for between about 10 seconds and about 1800 seconds.

15. The method of claim 13, wherein the plasma is formed from at least one gas selected from a group consisting of O₂, O₃, N₂O, NO₂, CO₂, CO, NH₃, and N₂.

16. A method for forming an interface protection layer in a thin film transistor comprising:
forming an interface protection layer having a thickness less than 500 Å on a portion of an active layer, wherein the interface protection layer is a Ti layer or a Ta layer and the active layer is a metal oxide layer;
forming a source-drain electrode layer on the interface protection layer;
etching the source-drain electrode layer to form a channel in the source-drain electrode layer that exposes a portion of the interface protection layer;
exposing the portion of the interface protection layer exposed through the source-drain electrode layer to an oxygen containing plasma environment or a nitrogen containing plasma environment; and
selectively oxidizing or nitridizing an entire thickness of the exposed portion of the interface protection layer.

17. The method of claim 16, wherein exposing the portion of the interface protection layer to an oxygen containing plasma environment or a nitrogen containing plasma environment occurs in a chemical vapor deposition chamber.

18. The method of claim 16, wherein the active layer is fabricated from a material selected from a group consisting of InGaZnO, InGaZnON, ZnO, ZnON, ZnSnO, CdSnO, GaSnO, TiSnO, CuAlO, SrCuO, LaCuOS, GaN, InGaN, AlGaN and InGaAlN.

19. The method of claim 16, wherein the interface protection layer and the source-drain electrode layer are formed in a single chamber.

20. The method of claim 16, wherein selectively oxidizing or nitridizing the entire thickness of the portion of the interface layer does not oxidize or nitridize portions of the interface protection layer covered by the source-drain electrode layer.
